(19) United States
(12) Patent Application Publication
(10) Pub. No.: US 2006/0071260 A1
(43) Pub. Date: Apr. 6, 2006

(54) Semiconductor device and method of manufacturing the same

(76) Inventor: Hiroyuki Yamasaki, Yokohama-shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/235,063

(22) Filed: Sep. 27, 2005

(30) Foreign Application Priority Data
Sep. 27, 2004 (JP) 2004-280746

(51) Int. Cl. H01L 21/8242; H01L 29/94

(52) U.S. Cl. 257/301; 438/243; 257/296

(57) ABSTRACT

A semiconductor device includes a semiconductor substrate, an insulating film provided on the semiconductor substrate, the insulating film including an opening portion, a surface strap embedded in the opening portion, the surface strap comprising a semiconductor layer, a reaction preventing film provided on the surface strap, the reaction preventing film comprising a material different from that of the insulating film, a storage electrode of a trench capacitor provided in the semiconductor substrate, the storage electrode connecting electrically with the surface strap, and a source/drain region provided on a surface of the semiconductor substrate, the source/drain region connecting electrically with the storage electrode via the surface strap.

### CROSS-REFERENCE TO RELATED APPLICATIONS

This application is based upon and claims the benefit of priority from prior Japanese Patent Application No. 2004-280746, filed Sep. 27, 2004, the entire contents of which are incorporated herein by reference.

### BACKGROUND OF THE INVENTION

1. Field of the Invention

The present invention relates to a semiconductor device including a surface strap and a method of manufacturing the same.

2. Description of the Related Art

In recent years, along the progress of semiconductor technologies, in particular, along the progress of microfabrication technologies, the miniaturization and high integration of memory cells have been progressed rapidly, and thereby, problems concerning memory retention property of memory cells have come up to the surface.

For example, in a DRAM in which a memory cell is configured by a MOS type transistor and a capacitor, the capacitor capacity is tend to decrease owing to the decrease of the capacity area accompanying with high integration. As a result, memory contents are read wrongly or software error that the memory contents are destructed by α rays have become problems.

In order to solve the problems, it is important not to decrease the capacitor capacity even if a memory cell is miniaturized.

Consequently, in the DRAM, various efforts have been made conventionally to ensure a sufficient capacitor capacity in order not to deteriorate an information storage function owing to high integration and miniaturization. As a typical example, the adoption of a trench capacitor is known.

As one of the structures for connecting a storage electrode of a trench capacitor and a source/drain of a MOS transistor, a surface strap structure (Jpn. Pat. Appln. KOKAI Publication Nos. 10-50964 and 2000-91520) has been known.

However, in the case of using the surface strap structure, a problem occurs as shown below. This problem is explained with reference to FIGS. 21 and 22.

FIG. 21 shows a cross sectional view of a DRAM in the course of its fabrication. More specifically, FIG. 21 shows a cross section at the stage where after the formation of a surface strap 91 comprising a polycrystalline silicon layer, an oxide film based insulating film 93 is deposited on the entire surface so as to fill in an opening portion 92 opened in advance for forming the surface strap 91. The oxide film based insulating film is an insulating film containing oxygen, and is typically a silicon oxide film.

In FIG. 21, reference numeral 81 denotes a silicon substrate, 82 denotes an embedded type isolation insulating film for shallow trench isolation (STI), 83 denotes a collar oxide film, 84 denotes a storage electrode of a trench capacitor, 85 to 88 denote MOS transistors in the course of fabrication, 89 denotes a spacer (gate side wall insulating film), and 90 denotes an oxide film based insulating film.

The MOS transistors 85 to 88 in the course of fabrication are ones after the steps of forming a gate insulating film, a gate electrode, an extension, and the spacer 89. In the figure, for simplicity, the gate electrode film and the gate electrode are not distinguished, and the extension is omitted.

The surface strap 91 is formed as below. That is, the surface strap 91 is formed by depositing the polycrystalline silicon layer on the entire surface so as to fill up the opening portion 92, thereafter, etching back the polycrystalline silicon layer by reactive ion etching (RIE) process.

After the step of FIG. 21, as shown in FIG. 22, oxide film based insulating films 90, 93 are etched back, thereby the insulating film 93 is selectively left on the surface strap 91.

The insulating film 93 is used, in a salicide process to be performed later, as a reaction preventing film (salicide block) for preventing the surface of the surface strap 91 from being silicided.

Here, the surface strap 91 is formed by etching back the polycrystalline silicone layer, as described above. Therefore the height (thickness) of the surface strap 91 becomes uneven in the wafer surface.

FIGS. 23 and 24 show cross sectional views of the portions including the high surface strap 91 in the DRAM corresponding to FIGS. 21 and 22. As shown in FIG. 24, in the portion including the high surface strap 91, the insulating film 93 on the surface strap 91 is eliminated during the oxide film based insulating films 90, 93 are etched back. Therefore in the salicide process, the surface of the surface strap 91 is silicided.

When the surface of the surface strap 91 is silicided, there occurs the problem that device characteristics such as DRAM retention characteristic are deteriorated.

### BRIEF SUMMARY OF THE INVENTION

A semiconductor device according to an aspect of the present invention comprises a semiconductor substrate; an insulating film provided on the semiconductor substrate, the insulating film including an opening portion; a surface strap embedded in the opening portion, the surface strap comprising a semiconductor layer; a reaction preventing film provided on the surface strap, the reaction preventing film comprising a material different from that of the insulating film; a storage electrode of a trench capacitor provided in the semiconductor substrate, the storage electrode connecting electrically with the surface strap; and a source/drain region provided on a surface of the semiconductor substrate, the source/drain region connecting electrically with the storage electrode via the surface strap.

A semiconductor device according to another aspect of the present invention comprises a semiconductor substrate; a surface strap provided on the semiconductor substrate, the surface strap comprising a semiconductor layer; a reaction preventing film provided on the semiconductor substrate, the reaction preventing film covering an upper surface and side surfaces of the surface strap; a storage electrode of a trench capacitor provided in the semiconductor substrate, the storage electrode connecting electrically with the surface strap; and a source/drain region provided on the surface of the semiconductor substrate, the source/drain region connecting electrically with the storage electrode via the surface strap.

A method of manufacturing a semiconductor device according to an aspect of the present invention comprises forming an insulating film on a semiconductor substrate comprising a storage electrode and a source/drain region of a trench capacitor, the storage electrode being formed inside of the semiconductor substrate and the source/drain region being formed on a surface of the semiconductor substrate; exposing an upper surface of the storage electrode by opening an opening portion in the insulating film; forming a semiconductor layer on the insulating film, the semiconductor layer filling up the opening portion; forming a surface strap in the opening portion by etching back the semiconductor layer, the surface strap being embedded in the opening portion up to middle of depth of the opening portion and comprising the semiconductor layer; forming a reaction preventing film to prevent reaction of the surface strap on a region including the insulating film and the opening portion, the reaction preventing film being embedded in the opening portion and comprising a film to be etched at an etching rate which is smaller than that of the insulating film; and removing the reaction preventing film outside of the opening portion by etching back the reaction preventing film and the insulating film under a condition that the etching rate of the reaction preventing film becomes smaller than that of the insulating film.

A method of manufacturing a semiconductor device according to another aspect of the present invention comprises forming an insulating film on a semiconductor substrate comprising a storage electrode and a source/drain region of a trench capacitor, the storage electrode being formed inside of the semiconductor substrate and the source/drain region being formed on a surface of the semiconductor substrate; opening an opening portion in the insulating film; forming a semiconductor layer on the insulating film, the semiconductor layer filling up the opening portion; forming a surface strap in the opening portion by etching back the semiconductor layer, the surface strap being embedded in the opening portion up to middle of depth of the opening portion and comprising the semiconductor layer; widening a diameter of the opening portion by etching the insulating film; forming a reaction preventing film to prevent reaction of the surface strap on a region including the insulating film and the opening portion, the reaction preventing film being embedded in the opening portion having the widened diameter and comprising a film to be etched at an etching rate which is smaller than that of the insulating film; and removing the reaction preventing film outside of the opening portion by etching back the reaction preventing film and the insulating film under a condition that the etching rate of the reaction preventing film becomes smaller than that of the insulating film.

### BRIEF DESCRIPTION OF THE SEVERAL VIEWS OF THE DRAWING

FIG. 1 is a cross sectional view showing a method of manufacturing a semiconductor device according to a first embodiment;

FIG. 2 is a cross sectional view showing details of a trench capacitor of the semiconductor device in FIG. 1;

FIG. 3 is a cross sectional view showing the method of manufacturing the semiconductor device following FIG. 1;

FIG. 4 is a cross sectional view showing the method of manufacturing the semiconductor device following FIG. 3;

FIG. 5 is a cross sectional view showing the method of manufacturing the semiconductor device following FIG. 4;

FIG. 6 is a cross sectional view showing the method of manufacturing the semiconductor device following FIG. 5;

FIG. 7 is a cross sectional view showing the method of manufacturing the semiconductor device following FIG. 6;

FIG. 8 is a cross sectional view showing the method of manufacturing the semiconductor device following FIG. 7;

FIG. 9 is a cross sectional view showing the method of manufacturing the semiconductor device following FIG. 8;

FIG. 10 is a cross sectional view showing the method of manufacturing the semiconductor device following FIG. 9;

FIG. 11 is a cross sectional view showing details of a region including a MOS transistors, a surface strap, a salicide block and the trench capacitor at the stage of FIG. 10;

FIG. 12 is a cross sectional view showing a method of manufacturing a semiconductor device according to a second embodiment;

FIG. 13 is a cross sectional view showing the method of manufacturing the semiconductor device following FIG. 11;

FIG. 14 is a cross sectional view showing the method of manufacturing the semiconductor device following FIG. 12;

FIG. 15 is a cross sectional view showing the method of manufacturing the semiconductor device following FIG. 13;

FIG. 16 is a cross sectional view showing the method of manufacturing the semiconductor device following FIG. 14;

FIG. 17 is a cross sectional view showing the method of manufacturing the semiconductor device following FIG. 15;

FIG. 18 is a cross sectional view showing details of a region including a MOS transistor, a surface strap, a salicide block and a trench capacitor at the stage of FIG. 10;

FIG. 19 is a cross sectional view showing a method of manufacturing a semiconductor device according to a third embodiment;

FIG. 20 is a cross sectional view showing the method of manufacturing the semiconductor device following FIG. 17;

FIG. 21 is a cross sectional view showing a method of manufacturing a DRAM including a conventional surface strap;

FIG. 22 is a cross sectional view showing the method of manufacturing the DRAM following FIG. 20;

FIG. 23 is a cross sectional view for explaining the problem with a method of manufacturing a DRAM including a conventional surface strap; and

FIG. 24 is a cross sectional view for explaining problem with the method of manufacturing the DRAM following FIG. 22.

### DETAILED DESCRIPTION OF THE INVENTION

Embodiments of the present invention will be explained with reference to the accompanying drawings hereinafter.

### First Embodiment

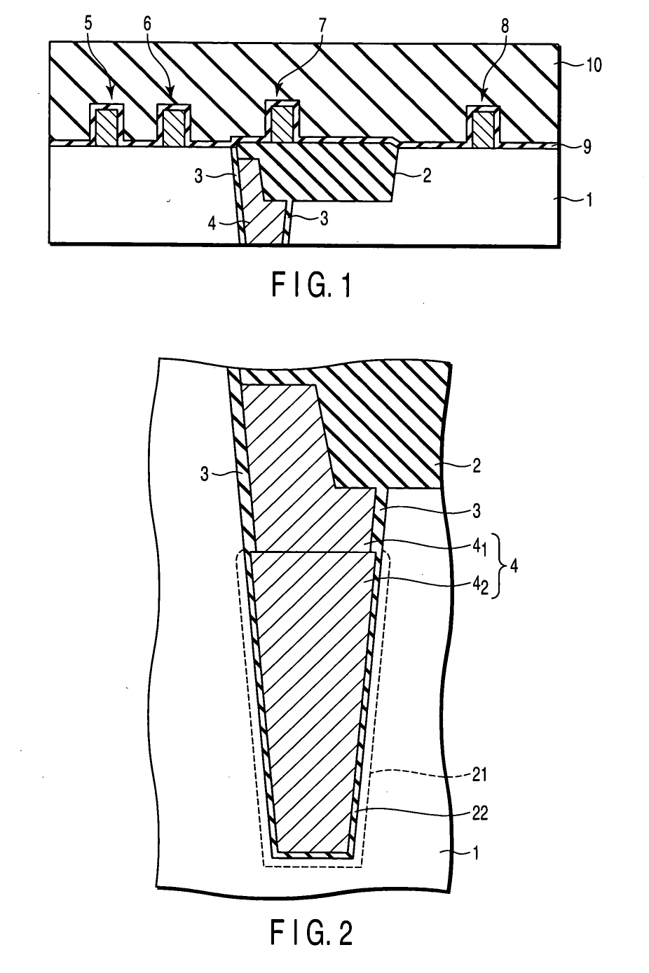

FIGS. 1 to 9 are cross sectional views each showing a method of manufacturing a semiconductor device according to a first embodiment. More specifically, they are cross sectional views each showing a method of manufacturing an embedded DRAM including a surface strap.

FIG. 1 is a cross sectional view of the embedded DRAM in the course of fabrication, and shows a cross sectional view at the stage where an oxide film based interlayer insulating film 10 is deposited on the entire surface of a silicon substrate 1 on which MOS transistors 5 to 8 in the course of fabrication have been formed.

In FIG. 1, reference numeral 1 denotes a silicon substrate, 2 denotes an embedded type isolation insulating film for STI, 3 denotes a collar oxide film, 4 denotes a storage electrode of a trench capacitor, and 9 denotes an insulating film.

The MOS transistors 5 to 8 in the course of fabrication have been already subjected the process of depositing the insulating film 9 to be processed into a spacer (gate side wall insulating film), where a gate insulating film, a gate electrode, and an extension are formed. In the figure, for simplicity, the gate electrode film and the gate electrode are not distinguished, and the extension is omitted.

The oxide film based interlayer insulating film 10 is an insulating film containing oxygen, and generally, further contains silicon, and is, for example, an SA-CVD film. The MOS transistor 5 is a MOS transistor for a word line, the MOS transistor 6 is a MOS transistor for a word line, the MOS transistor 7 is a MOS transistor for a passing word line, and the MOS transistor 8 is a logic transfer gate.

FIG. 2 shows a detailed structure of the trench capacitor. In FIG. 2, reference numeral 4₁ denotes a first storage electrode (first polycrystalline silicon film containing impurities), 4₂ denotes a second storage electrode (second polycrystalline silicon film containing impurities), 21 denotes a diffusion layer (plate electrode), and 22 denotes a capacitor insulating film. The trench capacitor is formed by well-known method.

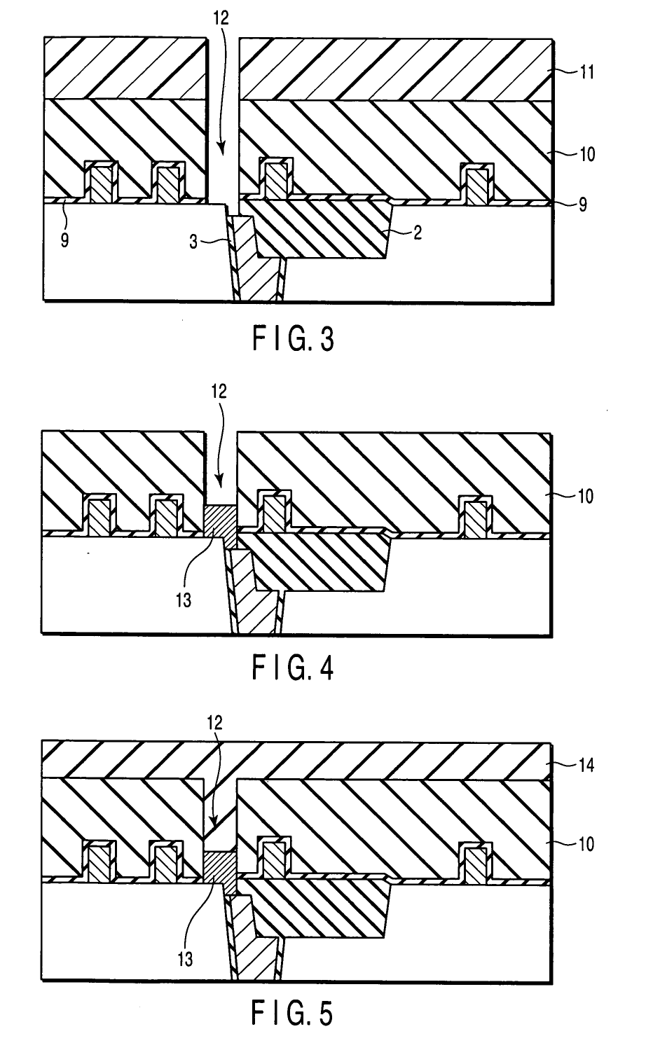

Next, as shown in FIG. 3, a resist pattern 11 for forming a surface strap is formed on the interlayer insulating film 10, and then, the interlayer insulating film 10, the insulating film 9, the collar oxide film 3 and the element isolation insulating film 2 are etched by RIE process using the resist pattern 11 as a mask, thereby an opening portion 12 is opened. After the opening portion 12 is opened, the resist pattern 11 is removed.

At the bottom of the opening portion 12, the surface of the silicon substrate 1 corresponding to a part of a region to be a source/drain region and a part of the upper surface of the storage electrode 4 are exposed.

Next, as shown in FIG. 4, a polycrystalline silicon layer to be processed into the surface strap 13 is deposited on the entire surface so as to fill up the opening portion 12, and thereafter, the polycrystalline silicon layer is etched back by RIE process, thereby the surface strap 13 is formed.

Here, since the amount of the polycrystalline silicon layer etched back is uneven in the wafer surface, the height (thickness) of the surface strap 13 becomes uneven in the wafer surface.

Further, the height of the surface strap 13 becomes uneven for the following reason as well. The step of forming the interlayer insulating film 10 includes a step of depositing an insulating film, and a step of planarizing the surface of the insulating film by CMP (chemical mechanical polishing) process. However, in the step of planarizing, the insulating film is not completely planarized, and the height of the insulating film becomes uneven. The uneven height of the insulating film causes the uneven height of the surface strap 13.

Next, as shown in FIG. 5, an insulating film 14 to be processed into a salicide block is deposited on the entire surface so as to fill up the opening portion 12 on the surface strap 13.

Here, the insulating film 14 is an insulating film different from the oxide film based interlayer insulating film 10, and is, for example, a nitride film based insulating film. The nitride film based insulating film is an insulating film containing nitrogen, and generally, further contains silicon, and is, for example, an Si₃N₄ film. By selecting a nitride film based insulating film such as the Si₃N₄ film as the insulating film 14, it is possible to etch the insulating film 14 and the interlayer insulating film 10 under a condition that the etching rate of the insulating film 14 becomes smaller than that of the interlayer insulating film 10.

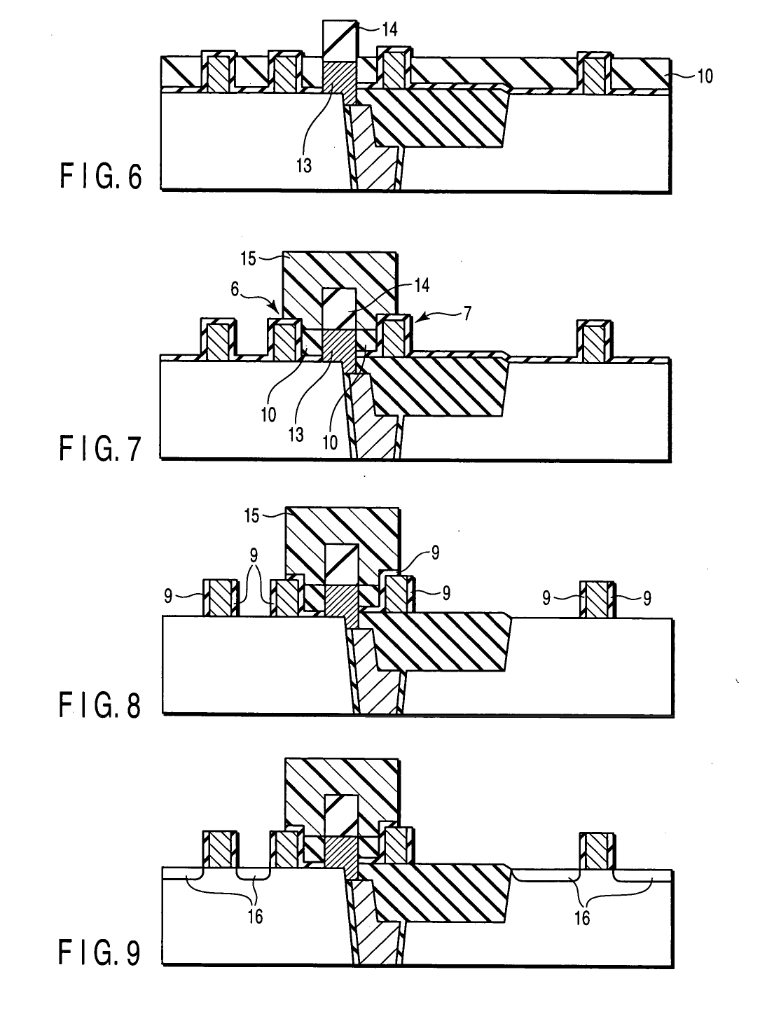

Next, as shown in FIG. 6, the interlayer insulating film 10 and the insulating film 14 are etched back by RIE process, and a salicide block 14 is formed on the surface strap 13.

The condition for the RIE process at this time is a condition that the etching rate of the insulating film 14 becomes smaller than that of the interlayer insulating film 10. Specifically, a mixed gas containing C₄F₈, CO and Ar is employed as an etching gas.

By performing etch back under the condition for the RIE process, it is possible to surely make the insulating film 14 left on the surface strap 13 even though there is an uneven height of the surface strap 13 in the wafer surface, and to surely form the salicide block 14 on the surface strap 13.

Next, as shown in FIG. 7, a resist 15 is formed which covers the surface strap 13, the salicide block 14, and further the interlayer insulating film 10 between the salicide block 14 and the MOS transistor 6, and the interlayer insulating film 10 between the salicide block 14 and the MOS transistor 7. Thereafter, the interlayer insulating film 10 that is exposed is removed by wet process.

Next, as shown in FIG. 8, the insulating film 9 is etched by RIE process using the resist 15 as a mask, and the insulating film 9 is left on the side walls of gate portions (gate electrode, gate insulating film). In this manner, a spacer (gate side wall insulating film) 9 is formed. Thereafter, the resist 15 is removed.

Next, as shown in FIG. 9, a source/drain region 16 is formed by well-known ion implantation process and anneal process.

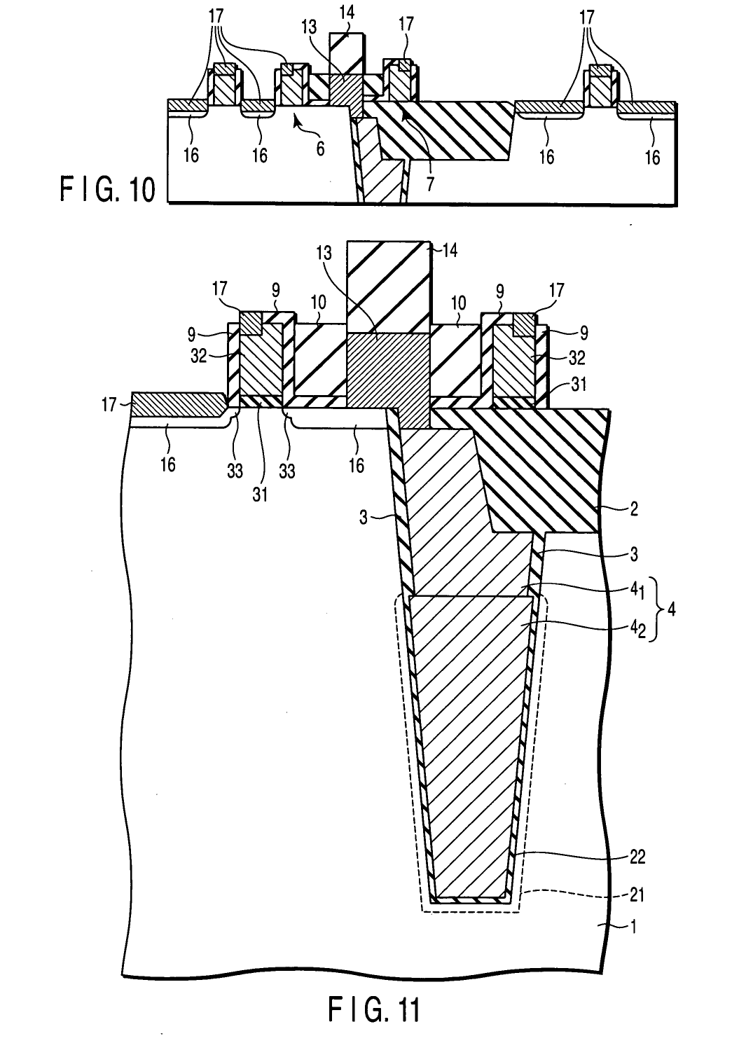

Next, as shown in FIG. 10, a metal silicide film 17 is formed on the gate electrode and the source/drain region 16 by well-known salicide process.

Because the surface strap 13 is covered with the salicide block 14 at this time, the surface of the surface strap 13 is not silicided (alloyed).

FIG. 11 shows a detailed cross sectional view of a region including the MOS transistors 6, 7, the surface strap 13, the salicide block 14 and the trench capacitor at this stage. In FIG. 11, reference numeral 31 denotes a gate insulating film, 32 denotes a gate electrode, and 33 denotes an extension.

Thereafter, the known steps continue to complete the DRAM.

As described above, according to the present embodiment, it is possible to form the salicide block 14 on the surface strap 13 even when there is unevenness in the height of the surface strap 13. Consequently, it is possible to suppress the silicidation of the surface strap 13 during the salicide process which causes the deterioration of device characteristics such as retention.

### Second Embodiment

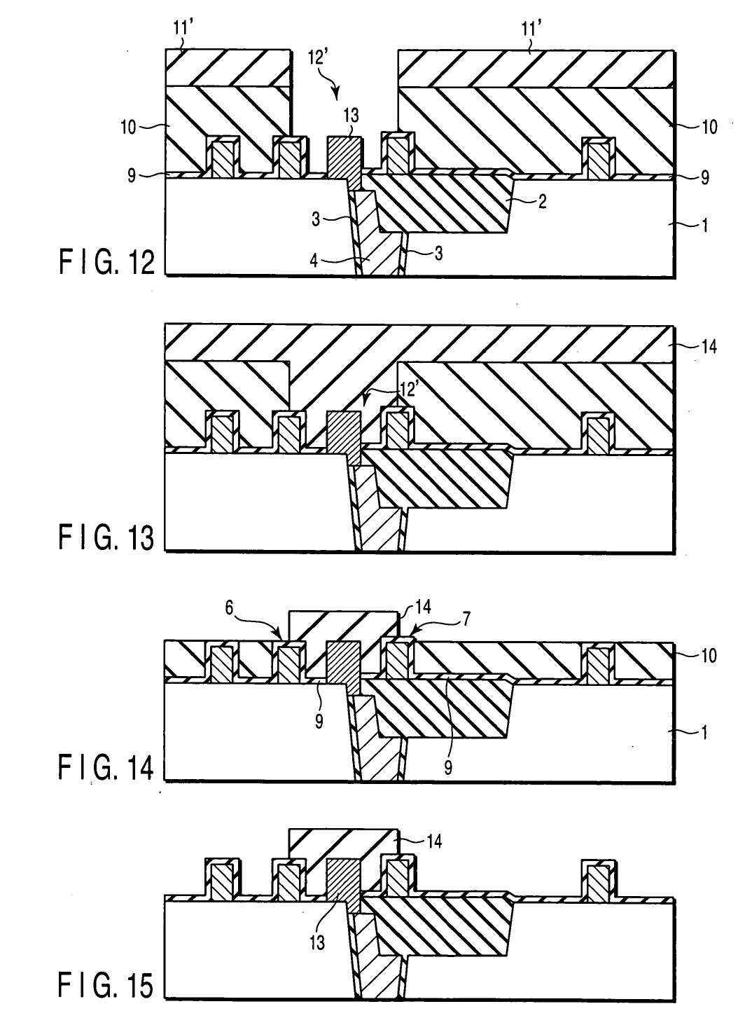

FIGS. 12 to 17 are cross sectional views each showing a method of manufacturing a semiconductor device according to a second embodiment. The same components as those shown in FIGS. 1 to 10 are denoted by the same reference numerals in FIGS. 12 to 17, and the detailed description thereof is omitted.

First, the steps up to FIG. 4 in the first embodiment are carried out.

Next, as shown in FIG. 12, a resist pattern 11′ including a wider opening portion than that of the resist pattern 11 is formed on the interlayer insulating film 10, and thereafter, the interlayer insulating film 10 is etched by wet process using the resist pattern 11′ as a mask such that an opening portion 12′ that is wider than the opening portion 12 is formed.

Next, as shown in FIG. 13, an insulating film (salicide block) 14 is deposited on the entire surface so as to fill up the opening portion 12′.

Next, as shown in FIG. 14, the interlayer insulating film 10 and the insulating film 14 are etched back by RIE process under a condition that the etching rate of the insulating film 14 becomes smaller than that of the interlayer insulating film 10. Then, the insulating film 14 is left on the surface strap 13 and the circumferential area thereof (the insulating film 9 on the silicon substrate 1, the insulating film 9 on the gate electrodes of the MOS transistors 6, 7). That is, the salicide block 14 that covers the surface strap 13 is formed in self-aligning manner such that the upper surface and the side surfaces of the surface strap 13 are not exposed.

By performing etch back under the condition for the RIE process, it is possible to surely form the salicide block 14 on the surface strap 13 even when there is an uneven height of the surface strap 13 in the wafer surface.

Next, as shown in FIG. 15, the interlayer insulating film 10 is selectively removed by wet process using the salicide block 14 as a mask.

At this time, the surface strap 13 is covered with the salicide block 14 formed in self-aligning manner, therefore, it is possible to prevent a medical solution used in the wet process from going into the surface strap 13 and the surface strap 13 from being exposed.

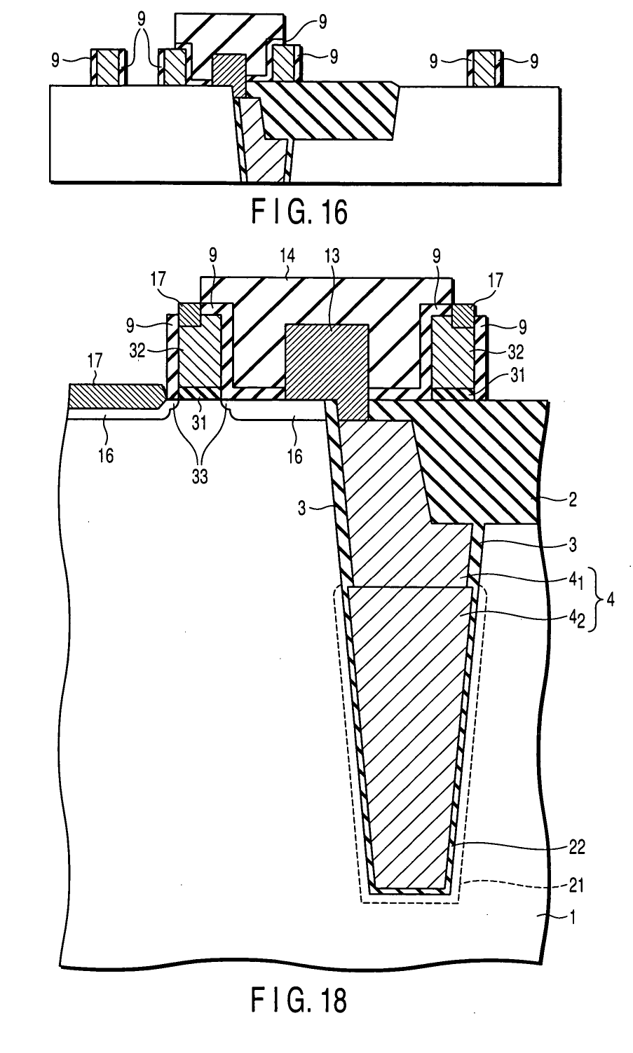

Next, as shown in FIG. 16, the insulating film 9 is etched by RIE process, and the insulating film (spacer) 9 is left on the side walls of the gate portion (gate electrode, gate insulating film).

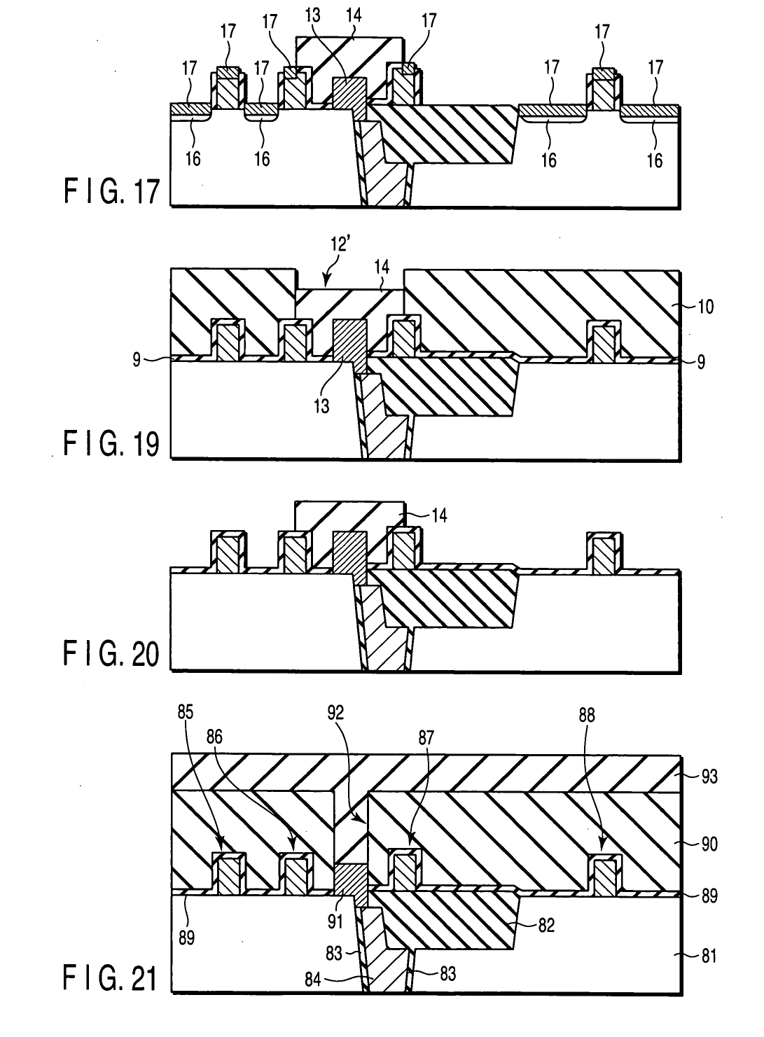

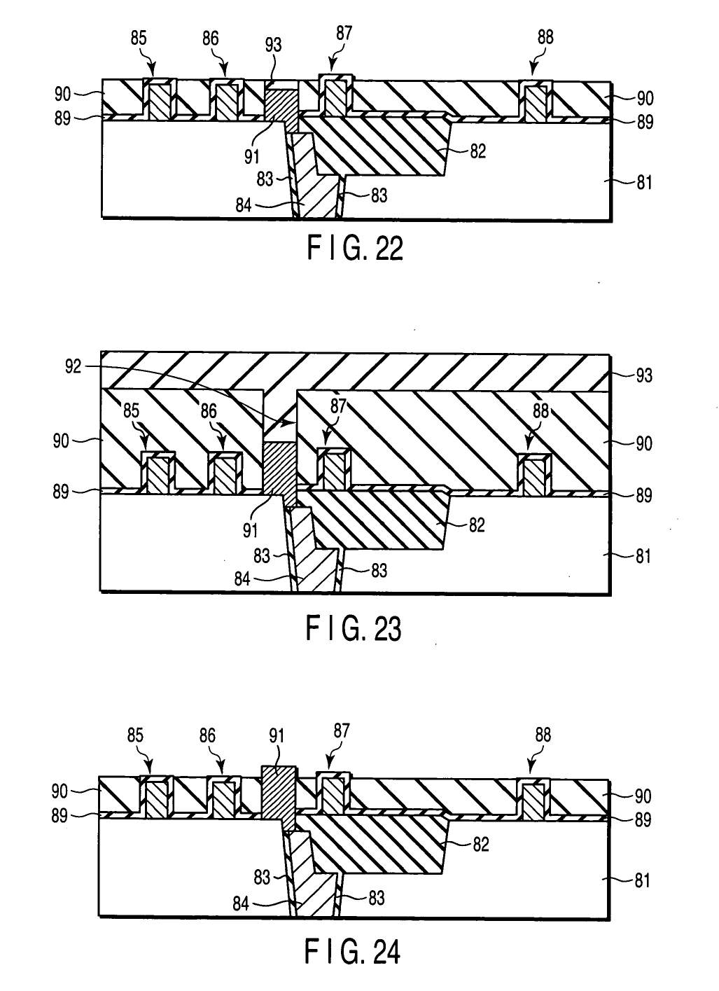

Next, as shown in FIG. 17, a source/drain region 16 is formed by well-known ion implantation process and anneal process, and thereafter, a metal silicide film 17 is formed on the gate electrode and the source/drain region 16 by well-known salicide process.

At this time, the surface strap 13 is covered with the insulating film (salicide block) 14, therefore, the surface of the surface strap 13 is not silicided.

FIG. 18 shows a detailed cross sectional view of a region including the MOS transistors 6, 7, the surface strap 13, the salicide block 14 and the trench capacitor at this stage.

Thereafter, the known steps continue to complete the DRAM.

As described above, according to the present embodiment, it is possible to form the salicide block 14 on the surface strap 13 even when there is unevenness in the height of the surface strap 13. Consequently, it is possible to suppress the silicidation of the surface strap 13 during the salicide process which causes the deterioration of device characteristics such as retention.

Further, according to the present embodiment, the salicide block 14 is formed in self-aligning manner, and therefore, no alignment displacement occurs between the salicide block 14 and the surface strap 13. For this reason, in the wet process of removing the interlayer insulating film 10 in FIG. 15, it is possible to prevent the surface strap 13 from being exposed.

### Third Embodiment

FIGS. 19 and 20 are cross sectional views each showing a method of manufacturing a semiconductor device according to a third embodiment. The same components as those shown in FIGS. 12 to 17 are denoted by the same reference numerals in FIGS. 19 and 20, and the detailed description thereof is omitted.

First, the steps up to FIG. 13 in the second embodiment are carried out.

Next, as shown in FIG. 19, the insulating film 14 is selectively etched back by RIE process, the insulating film 14 outside of the opening portion 12′ is removed, and further, the insulating film 14 in a region from the opening of the opening portion 12′ down to the depth not reaching the surface strap 13 is removed. As a consequence, a salicide block 14 whose upper surface is lower than the opening of the opening portion 12′ is formed.

The condition for the RIE process at this time is a condition that, for example, a mixed gas containing CHF₃ and O₂ is employed as an etching gas.

Next, as shown in FIG. 20, the interlayer insulating film 10 is selectively removed by wet process using the insulating film (salicide block) 14 as a mask.

The condition for the wet process at this time is a condition that, for example, a mixed liquid (BHF) containing NH₄F and HF is employed as an etching solution.

Next, in the same manner as in the step shown in FIG. 16 of the second embodiment, the insulating film 9 is etched by RIE process, and the insulating film (spacer) 9 is left on the side walls of the gate portion (gate electrode, gate insulating film).

Next, in the same manner as in the step shown in FIG. 17 of the second embodiment, a source/drain region 16 is formed by the ion implantation process and anneal process, and thereafter, a metal silicide film 17 is formed on the gate electrode and the source/drain region 16 by well-known salicide process.

At this time, the surface strap 13 is covered with the insulating film (salicide block) 14, therefore, the surface of the surface strap 13 is not silicided.

Thereafter, the known steps continue to complete the DRAM.

As described above, according to the present embodiment, it is possible to form the salicide block 14 on the surface strap 13 even when there is unevenness in the height of the surface strap 13. Consequently, it is possible to suppress the silicidation of the surface strap 13 during the salicide process which causes the deterioration of device characteristics such as retention.

Further, according to the present embodiment, the salicide block 14 is formed in self-aligning manner, and therefore, no alignment displacement occurs between the salicide block 14 and the surface strap 13. For this reason, in the wet step of removing the interlayer insulating film 10 in FIG. 15, it is possible to prevent the surface strap 13 from being exposed.

Furthermore, according to the present embodiment, the insulating film 9 is not etched in the step of etching the insulating film 14 (FIG. 19), and thus, the surfaces of the gate electrodes under the insulating film 9 are not exposed. Therefore, the surfaces of the gate electrodes are not etched in the step of removing the interlayer insulating film 10 in the next step.

This is compared with the step in FIG. 14 of the second embodiment. In the case of the step in FIG. 14, light generated due to the insulating film 9 being etched is detected, thereby the stop time of etching is determined. For this reason, there is a possibility that the insulating film 9 is etched and the surfaces of the gate electrodes are exposed. If the surfaces of the gate electrodes are exposed, there occurs an disadvantage that the surfaces of the gate electrodes are etched in the step of removing the interlayer insulating film 10 in the next step.

Meanwhile, the present invention is not limited to the first to third embodiments described above. Although the case of a DRAM has been explained in the above embodiments, the invention may be applied also to, for example, other semiconductor memory devices, and further, to other semiconductor devices than memory devices.

Moreover, the above embodiments have explained the case where the combination of the interlayer insulating film 10 and the insulating film 14 is an oxide film based insulating film and a nitride film-based insulating film. However, other combinations may also be employed. For example, the combinations which allow the etching rate of the insulating film 14 to be smaller than that of interlayer insulating film may be employed.

However, other combinations may also be employed, so long as the etching rate of the insulating film 14 can be made smaller than the etching rate of the interlayer insulating film 10.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A semiconductor device comprising:
a semiconductor substrate;
an insulating film provided on the semiconductor substrate, the insulating film including an opening portion;
a surface strap embedded in the opening portion, the surface strap comprising a semiconductor layer;
a reaction preventing film provided on the surface strap, the reaction preventing film comprising a material different from that of the insulating film;
a storage electrode of a trench capacitor provided in the semiconductor substrate, the storage electrode connecting electrically with the surface strap; and
a source/drain region provided on a surface of the semiconductor substrate, the source/drain region connecting electrically with the storage electrode via the surface strap.

2. A semiconductor device comprising:
a semiconductor substrate;
a surface strap provided on the semiconductor substrate, the surface strap comprising a semiconductor layer;
a reaction preventing film provided on the semiconductor substrate, the reaction preventing film covering an upper surface and side surfaces of the surface strap;
a storage electrode of a trench capacitor provided in the semiconductor substrate, the storage electrode connecting electrically with the surface strap; and
a source/drain region provided on the surface of the semiconductor substrate, the source/drain region connecting electrically with the storage electrode via the surface strap.

3. The semiconductor device according to claim 1,
wherein the insulating film is an insulating film containing oxygen, the semiconductor layer is a polycrystalline silicon layer, the reaction preventing film is an insulating film containing nitrogen, and the source/drain region is a source/drain region of a transistor of a memory cell of a DRAM.

4. The semiconductor device according to claim 3,
further comprising a metal silicide film on the source/drain region.

5. The semiconductor device according to claim 2,
wherein the insulating film is an insulating film containing oxygen, the semiconductor layer is a polycrystalline silicon layer, the reaction preventing film is an insulating film containing nitrogen, and the source/drain region is a source/drain region of a transistor of a memory cell of a DRAM.

6. The semiconductor device according to claim 5,
further comprising a metal silicide film on the source/drain region.

7. A method of manufacturing a semiconductor device comprising:
forming an insulating film on a semiconductor substrate comprising a storage electrode and a source/drain region of a trench capacitor, the storage electrode being formed inside of the semiconductor substrate and the source/drain region being formed on a surface of the semiconductor substrate;.
exposing an upper surface of the storage electrode by opening an opening portion in the insulating film;
forming a semiconductor layer on the insulating film, the semiconductor layer filling up the opening portion;
forming a surface strap in the opening portion by etching back the semiconductor layer, the surface strap being embedded in the opening portion up to middle of depth of the opening portion and comprising the semiconductor layer;
forming a reaction preventing film to prevent reaction of the surface strap on a region including the insulating film and the opening portion, the reaction preventing film being embedded in the opening portion and comprising a film to be etched at an etching rate which is smaller than that of the insulating film; and
removing the reaction preventing film outside of the opening portion by etching back the reaction preventing film and the insulating film under a condition that the etching rate of the reaction preventing film becomes smaller than that of the insulating film.

8. The method according to claim 7,
wherein the insulating film is an insulating film containing oxygen, the semiconductor layer is a polycrystalline silicon layer, the reaction preventing film is an insulating film containing nitrogen, and the source/drain region is a source/drain region of a transistor of a memory cell of a DRAM.

9. The method according to claim 8,
wherein the condition that the etching rate of the reaction preventing film becomes smaller than that of the insulating film is to use a mixed gas containing C₄F₈ and CO as an etching gas.

10. The method according to claim 8,
further comprising forming a metal silicide film on the source/drain region.

11. The method according to claim 9,
further comprising forming a metal silicide film on the source/drain region.

12. A method of manufacturing a semiconductor device comprising:
forming an insulating film on a semiconductor substrate comprising a storage electrode and a source/drain region of a trench capacitor, the storage electrode being formed inside of the semiconductor substrate and the source/drain region being formed on a surface of the semiconductor substrate;
opening an opening portion in the insulating film;
forming a semiconductor layer on the insulating film, the semiconductor layer filling up the opening portion;
forming a surface strap in the opening portion by etching back the semiconductor layer, the surface strap being embedded in the opening portion up to middle of depth of the opening portion and comprising the semiconductor layer;
widening a diameter of the opening portion by etching the insulating film;
forming a reaction preventing film to prevent reaction of the surface strap on a region including the insulating film and the opening portion, the reaction preventing film being embedded in the opening portion having the widened diameter and comprising a film to be etched at an etching rate which is smaller than that of the insulating film; and
removing the reaction preventing film outside of the opening portion by etching back the reaction preventing film and the insulating film under a condition that the etching rate of the reaction preventing film becomes smaller than that of the insulating film.

13. The method according to claim 12,
wherein the insulating film is an insulating film containing oxygen, the semiconductor layer is a polycrystalline silicon layer, the reaction preventing film is an insulating film containing nitrogen, and the source/drain region is a source/drain region of a transistor of a memory cell of a DRAM.

14. The method according to claim 13,
wherein the condition that the etching rate of the reaction preventing film becomes smaller than that of the insulating film is to use a mixed gas containing C₄F₈ and CO as an etching gas.

15. The method according to claim 13,
further comprising forming a metal silicide film on the source/drain region.

16. The method according to claim 14,
further comprising forming a metal silicide film on the source/drain region.
